(19) United States
(12) Patent Application Publication
(10) Pub. No.: US 2023/0101786 A1
(43) Pub. Date: Mar. 30, 2023

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Hyejeong KIM, Suwon-si (KR); Soohee KIM, Suwon-si (KR); Yoona KIM, Suwon-si (KR); Hyungseok PARK, Suwon-si (KR); Huichan YUN, Suwon-si (KR); Jaechul LEE, Suwon-si (KR); Jonghwa LEE, Suwon-si, Gyeonggi-do (KR); Seulgi JEONG, Suwon-si (KR); Yunju CHAE, Suwon-si (KR); Won Jong HWANG, Suwon-si (KR)

(21) Appl. No.: 17/893,458

(22) Filed: Aug. 23, 2022

(30) Foreign Application Priority Data
Aug. 23, 2021 (KR) 10-2021-0111064

(51) Int. Cl. G03F 7/11; G03F 7/20; G03F 7/40

(52) U.S. Cl. CPC G03F 7/11; G03F 7/202; G03F 7/40

(57) ABSTRACT

Provided are a hardmask composition including a polymer including a structural unit represented by Chemical Formula 1 and a structural unit represented by Chemical Formula 2, and a solvent, a hardmask layer manufactured from the hardmask composition, and a method of forming patterns from the hardmask composition, wherein the definitions of Chemical Formula 1 and Chemical Formula 2 are as described in the specification.

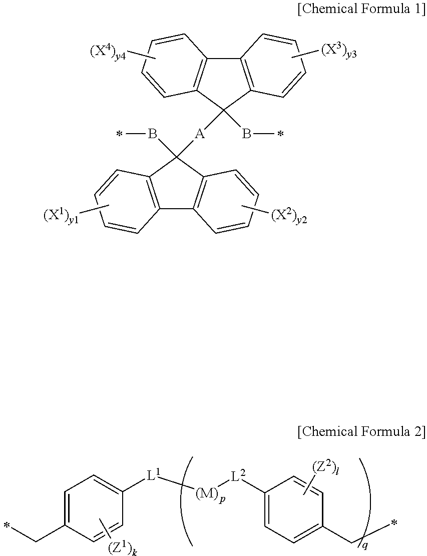

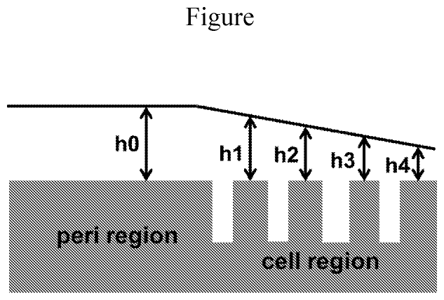

### CROSS-REFERENCE TO RELATED APPLICATION

This application claims priority to and the benefit of Korean Patent Application No. 10-2021-0111064 filed in the Korean Intellectual Property Office on Aug. 23, 2021, the entire contents of which are incorporated herein by reference.

### BACKGROUND

### 1. Field

Embodiments relate to a hardmask composition, a hardmask layer including a cured product of the hardmask composition, and a method of forming patterns using the hardmask composition.

### 2. Description of the Related Art

The semiconductor industry has developed an ultra-fine technique having a pattern of several to several tens nanometer size. Such an ultrafine technique calls for effective lithographic techniques.

### SUMMARY

A hardmask composition according to an embodiment may include a polymer including a structural unit represented by Chemical Formula 1 and a structural unit represented by Chemical Formula 2, and a solvent.

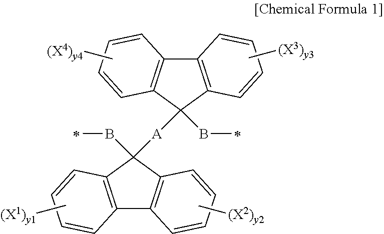

In Chemical Formula 1,

A may be a linking group including one or more benzene rings, and when A includes two or more benzene rings, the two or more benzene rings may form a condensed ring, or the two or more benzene rings may be linked to each other by a single bond, —O—, —S—, —NR¹— (wherein R¹ may be hydrogen, a C1 to C10 alkyl group, or a C6 to C30 aryl group), —C(═O)—, —(CH₂)ₘ—(CR²R³)ₙ—(CH₂)ₒ— (wherein R² and R³ may each independently be hydrogen, a C1 to C10 alkyl group, a C6 to C20 aryl group, or a C3 to C10 cycloalkyl group, m, n, and o may each independently be an integer from 0 to 10, and m+n+o may be 1 or more), or a combination thereof, and

B may be a C6 to C30 aromatic hydrocarbon ring substituted with one or more hydroxy groups or C1 to C10 alkoxy groups,

X¹ to X⁴ are each independently deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group,

y1 to y4 are each independently an integer of 0 to 4, and

*is a linking point;

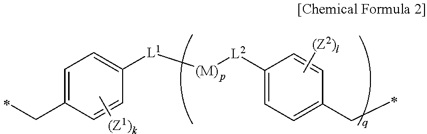

wherein, in Chemical Formula 2,

L¹ and L² may each independently be a single bond, a substituted or unsubstituted divalent C1 to C15 saturated aliphatic hydrocarbon group, or a substituted or unsubstituted divalent C2 to C15 unsaturated aliphatic hydrocarbon group,

M may be —O—, —S—, —SO₂—, or —C(═O)—,

Z¹ and Z² may each independently be deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group,

k, l, and q may each independently be an integer of 0 to 4,

p may be 0 or 1, and

* is a linking point.

A in Chemical Formula 1 may be any one selected from Group 1.

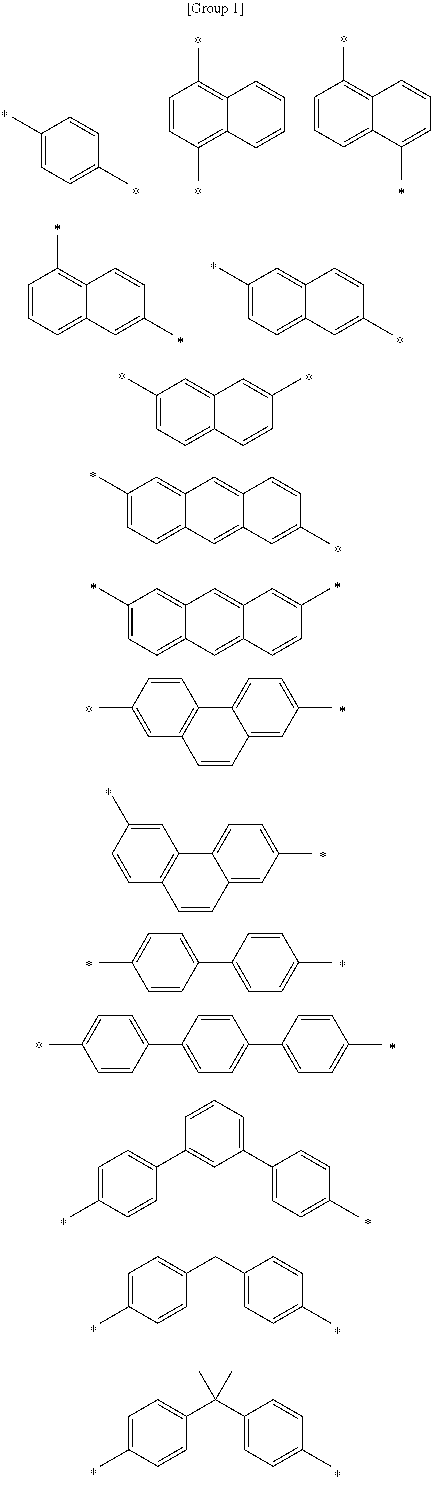

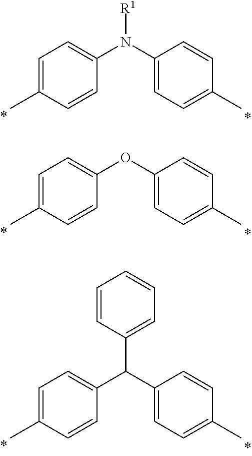

In Group 1,

R¹ may be hydrogen, a C1 to C10 alkyl group, or a C6 to C30 aryl group, and

* is a linking point.

B in Chemical Formula 1 may be any one selected from Group 2 substituted with one or more hydroxyl groups or C1 to C10 alkoxy groups.

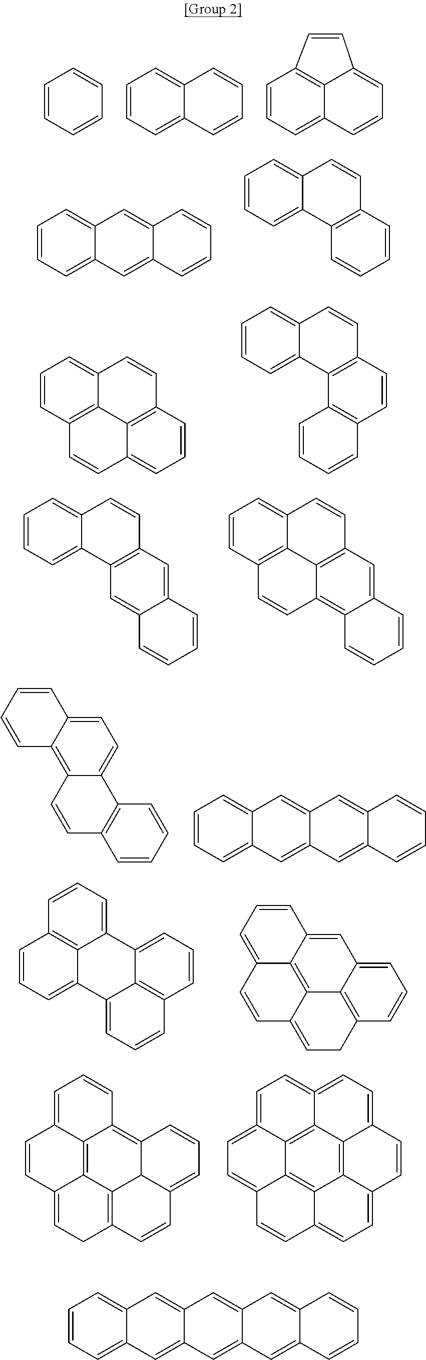

In Chemical Formula 2, L¹ and L² may each independently be a single bond, or a substituted or unsubstituted C1 to C10 alkylene group, M may be —O—, Z¹ and Z² may each independently be deuterium, a hydroxy group, a halogen, a substituted or unsubstituted C1 to C30 alkoxy group, or a substituted or unsubstituted C1 to C30 saturated aliphatic hydrocarbon group, k and 1 may each independently be one of integers of 0 to 2, and p and q may each be 0 or 1.

A in Chemical Formula 1 may be any one selected from Group 1-1.

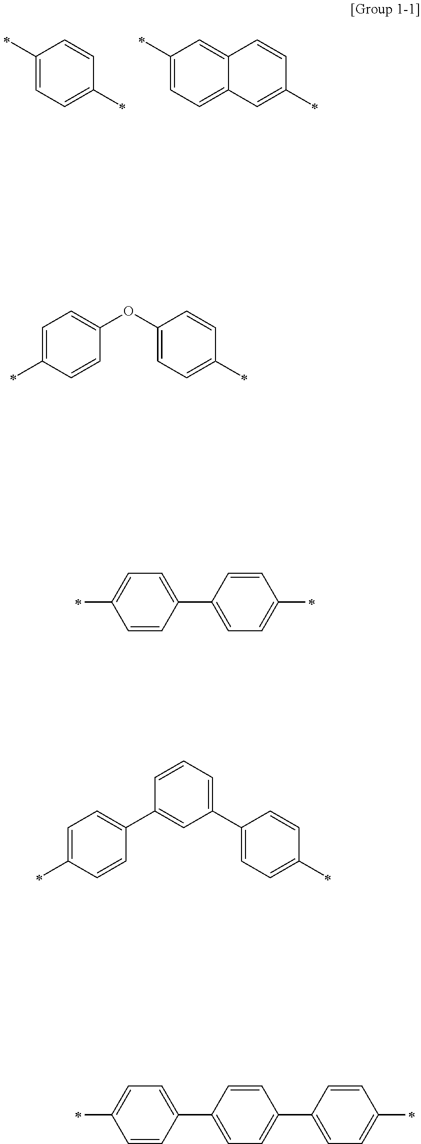

B in Chemical Formula 1 may be any one selected from Group 2-1.

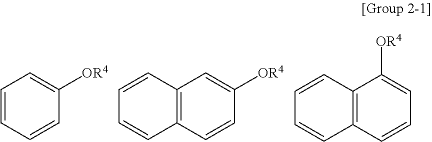

In Group 2-1,

R⁴ may be hydrogen, a C1 to C10 alkyl group, a C2 to C10 alkenyl group, or a C2 to C10 alkynyl group.

Chemical Formula 1 may be any one of Chemical Formula 1-1 to Chemical Formula 1-11.

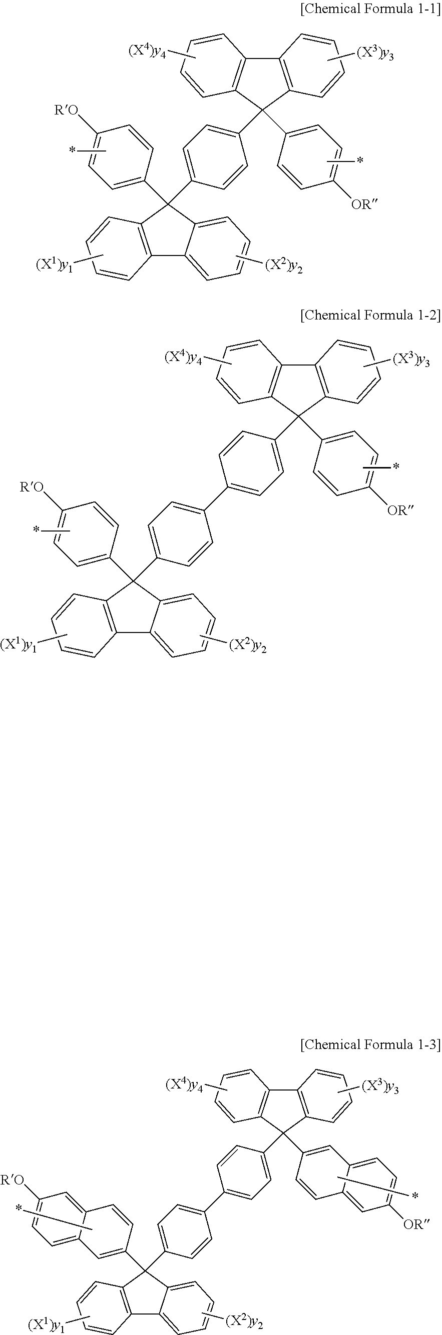

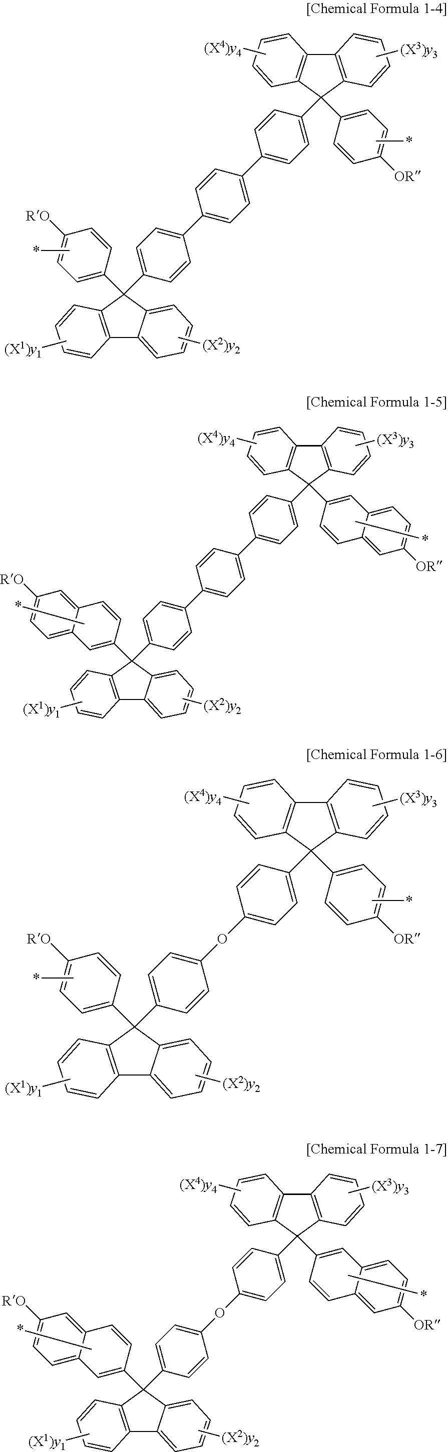

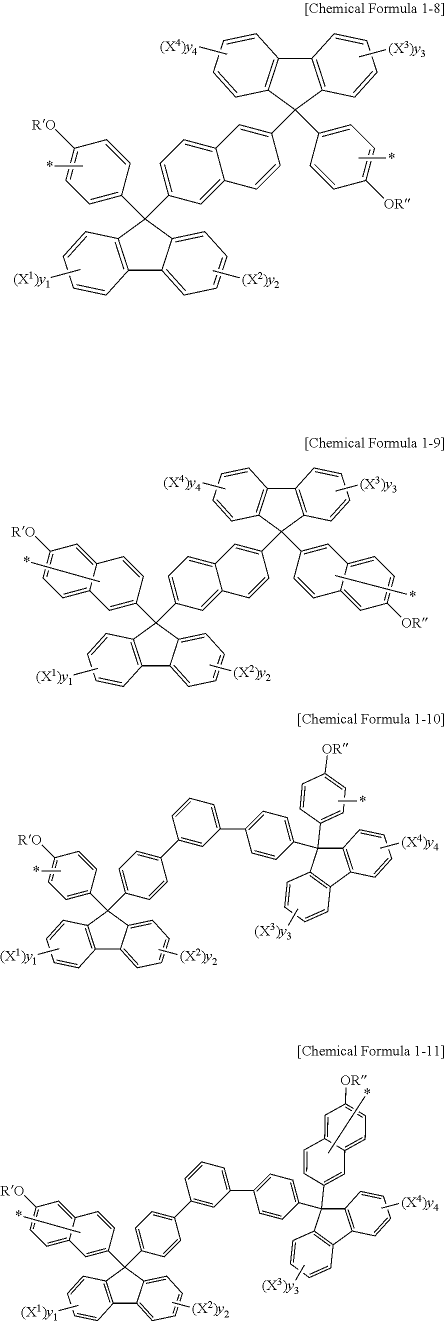

In Chemical Formula 1-1 to Chemical Formula 1-11,

R′ and R″ may each independently be hydrogen, a C1 to C10 alkyl group, a C2 to C10 alkenyl group, or a C2 to C10 alkynyl group,

X¹ to X⁴ are each independently deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group,

y1 to y4 are each independently an integer of 0 to 4, and

* is a linking point.

Chemical Formula 2 may be represented by Chemical Formula 2-1 or Chemical Formula 2-2.

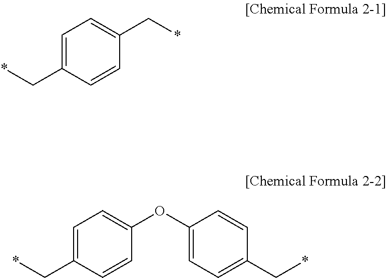 [SMILES: *Cc1ccc(C*)cc1 ; *Cc1ccc(Oc2ccc(C*)cc2)cc1]

The polymer may have a weight average molecular weight of about 1,000 g/mol to about 200,000 g/mol.

The polymer may be included in an amount of about 0.1 wt % to about 30 wt % based on the total weight of the hardmask composition.

The solvent may be propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

According to another embodiment, a hardmask layer may include a cured product of the aforementioned hardmask composition.

According to another embodiment, a method of forming patterns may include providing a material layer on a substrate, applying the hardmask composition on the material layer to form a hardmask layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching the exposed portion of the material layer.

The forming of the hardmask layer may include heat-treating at about 100° C. to about 1,000° C.

### BRIEF DESCRIPTION OF THE DRAWING

Features will become apparent to those of skill in the art by describing in detail example embodiments with reference to the attached drawing in which:

The FIGURE is a reference view schematically illustrating a cross-section of a hardmask layer in order to explain a method for evaluating gap-fill characteristics and planarization characteristics.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art. In the drawing FIGURE, the dimensions of layers and regions may be exaggerated for clarity of illustration. Like reference numerals refer to like elements throughout.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring. For example, the substituted C6 to C30 aryl group may be fused with another adjacent substituted C6 to C30 aryl group to form a substituted or unsubstituted fluorene ring.

As used herein, when a definition is not otherwise provided, “hetero” may refer to one including 1 to 3 heteroatoms selected from N, O, S, Se, and P.

As used herein, when a definition is not otherwise provided, “saturated aliphatic hydrocarbon group” includes a functional group in which all bonds between carbons are single bonds, e.g., an alkyl group or an alkylene group.

As used herein, when a definition is not otherwise provided, “unsaturated aliphatic hydrocarbon group” refers to a functional group in which an intercarbon bond includes one or more unsaturated bonds, and may include, e.g., a double bond or a triple bond, e.g., an alkenyl group, an alkynyl group, an alkenylene group, or an alkynylene group.

As used herein, when a definition is not otherwise provided, “aromatic hydrocarbon group” refers to a group having one or more hydrocarbon aromatic moieties, in which hydrocarbon aromatic moieties are linked by a single bond and hydrocarbon aromatic moieties are directly or indirectly fused with non-aromatic fused rings. More specifically, the substituted or unsubstituted aromatic hydrocarbon group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups.

As used herein, the term “aryl group” refers to a group having one or more hydrocarbon aromatic moieties, and broadly refers to a form in which hydrocarbon aromatic moieties are linked by a single bond and hydrocarbon aromatic moieties are directly or indirectly fused with non-aromatic fused rings. The aryl group may include a monocyclic, polycyclic or fused polycyclic (i.e., rings sharing adjacent pairs of carbon atoms) functional group.

As used herein, when specific definition is not otherwise provided, the term “combination” refers to mixing or copolymerization.

Also, as used herein, the polymer may include both an oligomer and a polymer.

Unless otherwise specified in the present specification, “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

There is a constant trend in the semiconductor industry to reduce a size of chips, and in order to cope with this demand, a line width of a resist should be patterned to have several tens of nanometers through lithography. Accordingly, a height of the resist may be limited to support the line width of the resist pattern, but a thin resist may have insufficient resistance in the etching process. In order to compensate for this, an auxiliary layer, which is called a hardmask layer, is used between a material layer for etching and a photoresist layer. This hardmask layer serves as an interlayer that transfers a fine pattern of the photoresist layer through selective etching and thus is required to have so sufficient etch resistance as to withstand the etching process for the pattern transfer.

A general hardmask layer that is formed in a chemical or physical deposition method may present difficulties in terms of low economic efficiency due to a large-scale equipment and a high process cost. Thus, a spin-coating technique for forming a hardmask layer may be used. The spin-coating technique may be an easier process to conduct than the general method, and a hardmask layer formed therefrom may exhibit better gap-fill characteristics and planarization characteristics.

To improve etch resistance of a hardmask layer, a carbon content of a hardmask composition may be increased, e.g., maximized. However, as the carbon content of the hardmask composition is increased, solubility of the composition in a solvent may be deteriorated, such that the spin-coating technique may be difficult to apply. Accordingly, a hardmask composition should exhibit good etch resistance without lowering solubility in a solvent.

An example embodiment may provide a hardmask composition for forming a hardmask that exhibits excellent gap-fill characteristics and planarization characteristics without deteriorating the etch resistance. An example embodiment may provide appropriate solubility of the hardmask composition in a solvent. In an example embodiment, carbon content in the hardmask composition may be increased by using a polymer including an aromatic hydrocarbon ring to improve etch resistance of a hardmask layer formed thereof, wherein the polymer includes quaternary carbon, which may improve solubility in a solvent. In an example embodiment, the polymer included in the hardmask composition includes a fluidity linking group to improve fluidity of the composition during the coating process, and thus the hardmask layer formed thereof may exhibit excellent gap-fill characteristics and planarization characteristics.

A hardmask composition according to an example embodiment may include a polymer including a structural unit represented by Chemical Formula 1 and a structural unit represented by Chemical Formula 2, and a solvent.

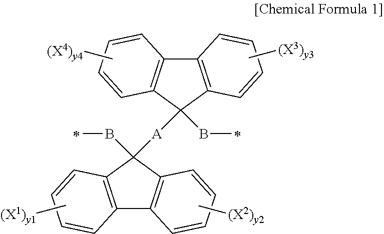

In Chemical Formula 1, A may be a linking group including one or more benzene rings. When A includes two or more benzene rings, the two or more benzene rings may form a condensed ring, or the two or more benzene rings may be linked to each other. The two or more benzene rings may be linked to each other by a single bond. The two or more benzene rings may be linked to each other by —O—. The two or more benzene rings may be linked to each other by —S—. The two or more benzene rings may be linked to each other by —NR¹— in which R¹ is hydrogen, a C1 to C10 alkyl group, or a C6 to C30 aryl group. The two or more benzene rings may be linked to each other by —C(═O)—. The two or more benzene rings may be linked to each other by —(CH₂)ₘ—(CR²R³)ₙ—(CH₂)ₒ— in which R² and R³ is each independently hydrogen, a C1 to C10 alkyl group, a C6 to C20 aryl group, or a C3 to C10 cycloalkyl group, m, n, and o are each independently an integer from 0 to 10, and m+n+o is 1 or more. The two or more benzene rings may be linked to each other by a combination of one or more of a single bond, —O—, —S—, —NR¹, —C(═O)—, or —(CH₂)ₘ—(CR²R³)ₙ—(CH₂)ₒ—.

In Chemical Formula 1, B may be a C6 to C30 aromatic hydrocarbon ring substituted with one or more hydroxy groups or C1 to C10 alkoxy groups.

In Chemical Formula, X¹ to X⁴ may each independently be deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group.

In Chemical Formula 1, y1 to y4 may each independently be an integer of 0 to 4.

In Chemical Formula 1, * is a linking point.

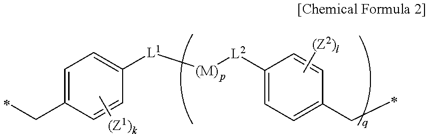

In Chemical Formula 2, L¹ and L² may each independently be a single bond, a substituted or unsubstituted divalent C1 to C15 saturated aliphatic hydrocarbon group, or a substituted or unsubstituted divalent C2 to C15 unsaturated aliphatic hydrocarbon group.

In Chemical Formula 2, M may be —O—, —S—, —SO₂—, or —C(═O)—.

In Chemical Formula 2, Z¹ and Z² may each independently be deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group.

In Chemical Formula 2, k, 1, and q may each independently be an integer of 0 to 4.

In Chemical Formula 2, p may be 0 or 1.

In Chemical Formula 2, * is a linking point.

As described above, the polymer in the composition according to the present example embodiment includes aromatic hydrocarbon rings in both the structural unit represented by Chemical Formula 1 and the structural unit represented by Chemical Formula 2, which may help to maximize a carbon content in the composition. In addition, the flexibility of the polymer may be increased by the structural unit represented by Chemical Formula 2. The flexible structure may increase a free volume of the polymer to improve a solubility of the composition containing it, and may increase a reflow during the baking process by lowering a glass transition temperature (Tg), which may help to improve gap-fill characteristics and planarization characteristics of the hardmask layer formed from such a composition.

In addition, the polymer includes two fluorenes per one structural unit represented by Chemical Formula 1, which may increase the carbon content in the polymer, and at the same time includes a quaternary carbon in Chemical Formula 1, which may help to provide a hardmask layer formed from the hardmask composition including the polymer with a high etch resistance and increased solubility in a solvent. In addition, the aromatic hydrocarbon rings of A and B of Chemical Formula 1 may cause interactions such as pi-pi stacking with other aromatic hydrocarbon rings in the polymer, and planarization characteristics of the hardmask layer formed from the composition including the same may be strengthened.

The structural unit represented by Chemical Formula 1 may be obtained by, e.g., performing a Grignard reaction between fluorenone and an organometallic reagent containing a ring corresponding to A of Chemical Formula 1, and additionally reacting the resulting product with an aromatic hydrocarbon compound corresponding to B of Chemical Formula 1, as can be seen from synthesis examples to be described below.

In an example embodiment, A in Chemical Formula 1 may be any one selected from Group 1:

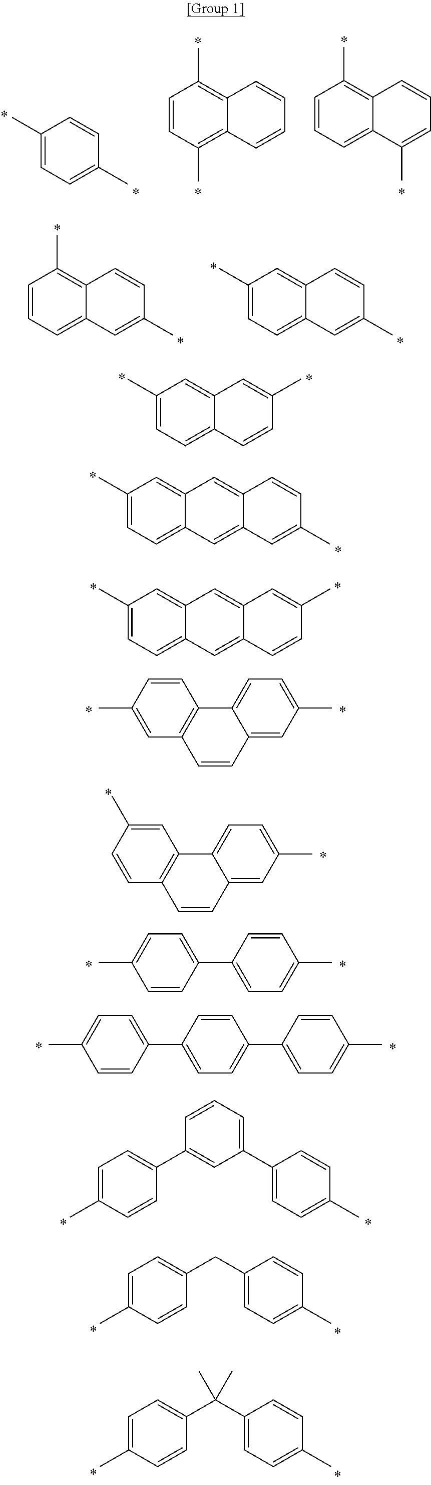

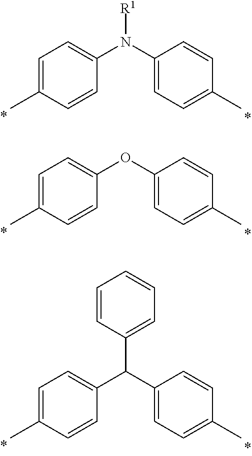

In Group 1, R¹ may be hydrogen, a C1 to C10 alkyl group, or a C6 to C30 aryl group, and * is a linking point.

In another example embodiment, A in Chemical Formula 1 may be any one selected from Group 1-1.

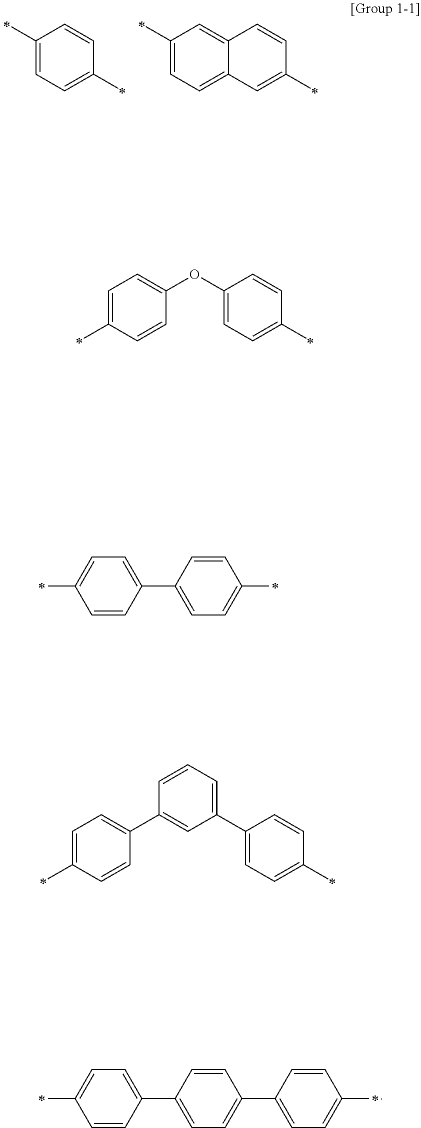

In an example embodiment, B in Chemical Formula 1 may be any one selected from Group 2 substituted with one or more hydroxyl groups or C1 to C10 alkoxy groups:

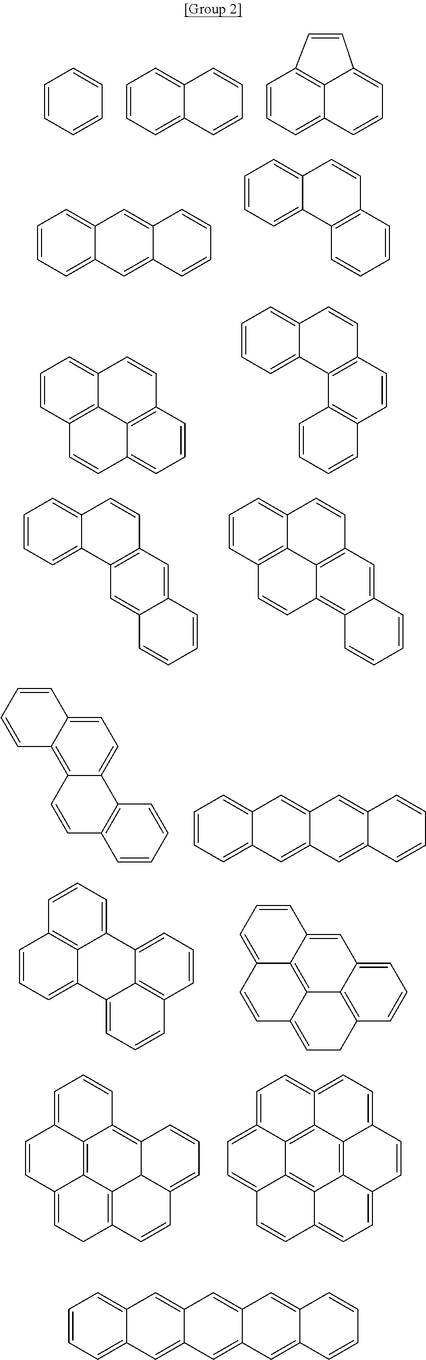

By substituting B with one or more hydroxy groups or C1 to C10 alkoxy groups, flexibility may be imparted to the polymer.

In another example embodiment, B in Chemical Formula 1 may be any one selected from Group 2-1.

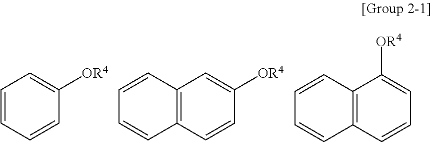

In Group 2-1, R⁴ may be hydrogen, a to C10 alkyl group, a to C10 alkenyl group, or a C2 to C10 alkynyl group.

Chemical Formula 1 may be represented by any one of Chemical Formula 1-1 to Chemical Formula 1-11:

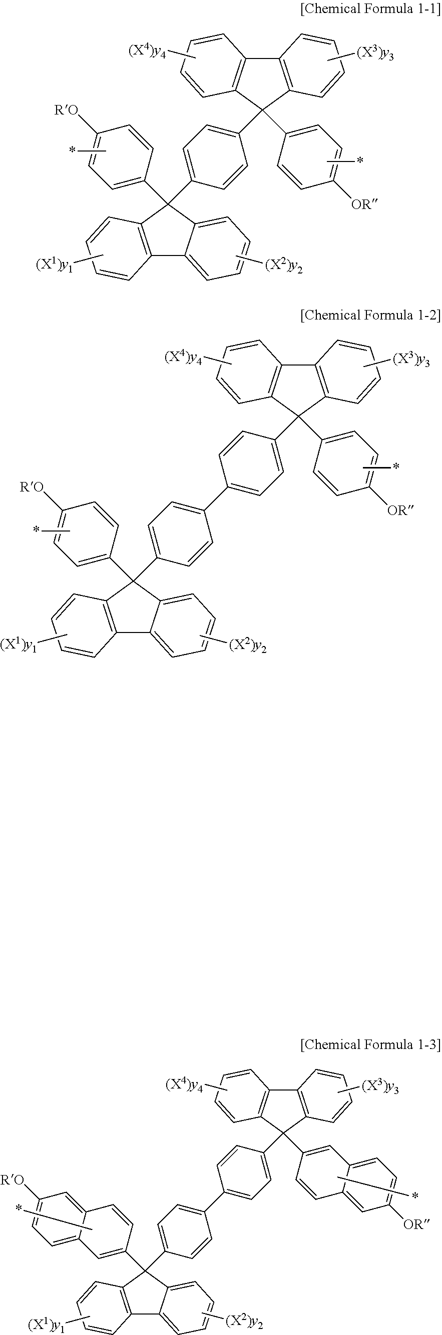

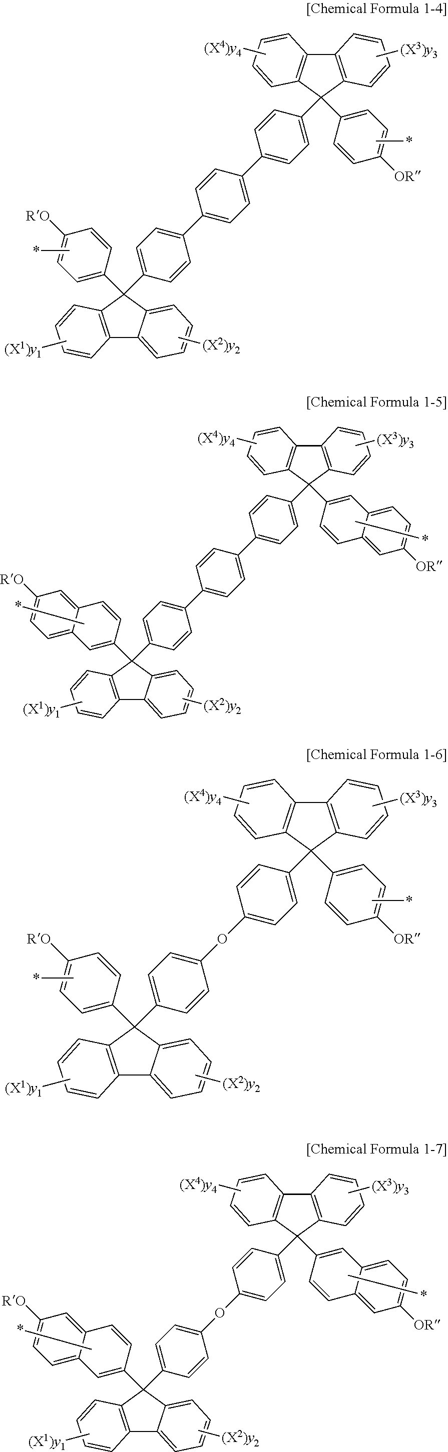

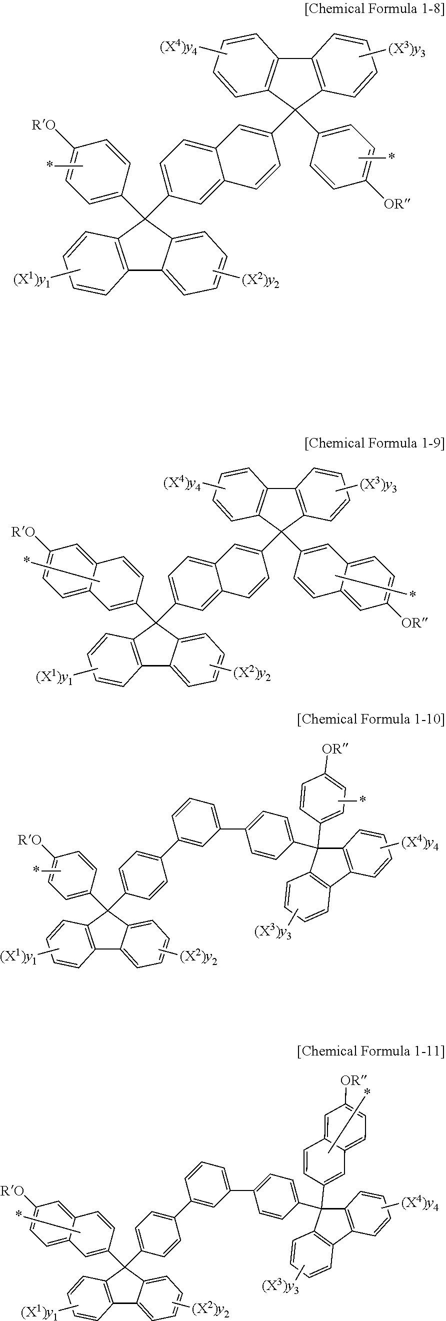

In Chemical Formula 1-1 to Chemical Formula 1-11, R′ and R″ may each independently be hydrogen, a C1 to C10 alkyl group, a C2 to C10 alkenyl group, or a C2 to C10 alkynyl group. The R′ and R″ may be the same as or different from each other.

For example, when R′ or R″ is a substituted or unsubstituted C1 to C10 alkyl group, it may be a methyl group, an ethyl group, a propyl group, a butyl group, a pentyl group, a hexyl group, a heptyl group, or an octyl group, e.g., a methyl group, an ethyl group, a propyl group, a butyl group, a pentyl group, or a hexyl group.

For example, when R′ or R″ is a substituted or unsubstituted C2 to C10 alkenyl group, it may have a structure including one or more double bonds, e.g., a vinyl group, a propenyl group, a butenyl group, a pentenyl group, or may be a hexenyl group.

For example, when R′ or R″ is a substituted or unsubstituted C2 to C20 alkynyl group, it may have a structure including one or more triple bonds, e.g., an ethynyl group, a propynyl group, a propargyl group, a butynyl group, a pentynyl group, or a hexynyl group.

In Chemical Formula 1-1 to Chemical Formula 1-11, X¹ to X⁴ may each independently be deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group.

In Chemical Formula 1-1 to Chemical Formula 1-11, y1 to y4 are each independently an integer of 0 to 4.

In an example embodiment, in Chemical Formula 2, L¹ and L² may each independently be a single bond, or a substituted or unsubstituted C1 to C10 alkylene group, M may be —O—, Z¹ and Z² may each independently be deuterium, a hydroxy group, a halogen atom, a substituted or unsubstituted C1 to C30 alkoxy group, or a substituted or unsubstituted C1 to C30 saturated aliphatic hydrocarbon group, p and q may each independently be 0 or 1, and k and 1 may each independently be an integer from 0 to 2.

In an example embodiment, Chemical Formula 2 may be represented by Chemical Formula 2-1 or Chemical Formula 2-2:

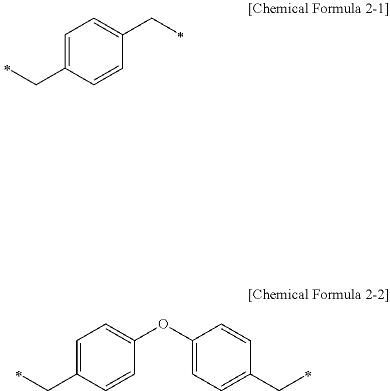

The polymer may have a weight average molecular weight of about 1,000 g/mol to about 200,000 g/mol. For example, the polymer may have a weight average molecular weight of about 1,000 g/mol to about 150,000 g/mol, for example about 1,000 g/mol to about 100,000 g/mol, for example about 1,200 g/mol to about 50,000 g/mol, or for example about 1,200 g/mol to about 10,000 g/mol. By having a weight average molecular weight in the above range, a carbon content and solubility in a solvent of the hardmask composition including the polymer may be adjusted and optimized.

The polymer may be included in an amount of about 0.1 wt % to about 30 wt % based on the total weight of the hardmask composition. For example, the polymer may be included in an amount of about 0.2 wt % to about 30 wt %, for example about 0.5 wt % to about 30 wt %, for example about 1 wt % to about 30 wt %, for example about 1.5 wt % to about 25 wt %, for example about 2 wt % to about 20 wt %. By including the compound within the above range, a thickness, a surface roughness, and a planarization degree of the hardmask may be easily adjusted.

The hardmask composition according to an example embodiment may include a solvent. In an example embodiment, the solvent may be at least one selected from propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. Any suitable solvent may be selected to provide sufficient solubility and/or dispersibility for the polymer.

The hardmask composition may further include additives such as a surfactant, a crosslinking agent, a thermal acid generator, and a plasticizer.

The surfactant may include, e.g., a fluoroalkyl-based compound, an alkylbenzenesulfonate, an alkylpyridinium salt, polyethylene glycol, a quaternary ammonium salt, or the like.

The crosslinking agent may be, e.g., a melamine-based, a substituted urea-based, or a polymer-based crosslinking agent. The crosslinking agent may have at least two crosslinking substituents, and may be, e.g., a compound such as methoxymethylated glycouryl, butoxymethylated glycouryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In addition, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may be, e.g., an acid compound, for example p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid and/or 2,4,4,6-tetrabromocyclohexadienone, benzointosylate, 2-nitrobenzyltosylate, and other organic sulfonic acid alkyl esters.

According to another example embodiment, a hardmask layer including a cured product of the aforementioned hardmask composition is provided.

Hereinafter, a method of forming patterns using the aforementioned hardmask composition is described.

A method of forming patterns according to an example embodiment includes providing a material layer on a substrate, applying a hardmask composition including the aforementioned polymer and solvent on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate.

The material layer is a material to be finally patterned, for example a metal layer such as an aluminum layer and a copper layer, a semiconductor layer such as a silicon layer, or an insulation layer such as a silicon oxide layer and a silicon nitride layer. The material layer may be formed through a method such as a chemical vapor deposition (CVD) process.

The hardmask composition is the same as described above, and may be applied by spin-on coating in a form of a solution. Herein, a thickness of the hardmask composition may be, e.g., about 50 Å to about 200,000 Å.

The heat-treating of the hardmask composition may be performed, e.g., at about 100° C. to about 1,000° C. for about 10 seconds to about 1 hour.

The heat treatment of the hardmask composition may include a plurality of heat treatment processes, e.g., a first heat treatment process, and a second heat treatment process.

In an example embodiment, the heat treatment of the hardmask composition may include, e.g., one heat treatment process performed at about 100° C. to about 1000° C. for about 10 seconds to about 1 hour, and for example, the heat treatment may be performed under an atmosphere of air or nitrogen, or an atmosphere having oxygen concentration of 1 wt % or less.

In an example embodiment, the heat-treating of the hardmask composition may include, e.g., a first heat-treating process performed at about 100° C. to about 1,000° C., for example about 100° C. to about 800° C., for example about 100° C. to about 500° C., or for example about 100° C. to about 400° C. for about 10 seconds to about 1 hour, and for example, a second heat-treating process performed at about 100° C. to about 1,000° C., for example about 300° C. to 1,000° C., for example, about 500° C. to 1,000° C., or for example about 500° C. to 800° C. for about 10 seconds to about 1 hour consecutively. For example, the first and second heat-treating processes may be performed under an atmosphere of air or nitrogen, or an atmosphere having oxygen concentration of 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an example embodiment, the forming of the hardmask layer may include a UV/Vis curing process and/or a near IR curing process.

In an example embodiment, the forming of the hardmask layer may include at least one of a first heat-treating process, a second heat-treating process, a UV/Vis curing process, and a near IR curing process, or may include two or more processes consecutively

In an example embodiment, the method may further include forming a silicon-containing thin layer on the hardmask layer. The silicon-containing thin layer may be, e.g., formed of a material, for example SiCN, SiOC, SiON, SiOCN, SiC, SiO, and/or SiN, or the like.

In an example embodiment, the method may further include forming a bottom antireflective coating (BARC) on the silicon-containing thin layer or on the hardmask layer before forming the photoresist layer.

In an example embodiment, exposure of the photoresist layer may be performed using, for example ArF, KrF, or EUV. After exposure, heat-treating may be performed at about 100° C. to about 700° C.

In an example embodiment, the etching process of the exposed part of the material layer may be performed through a dry etching process using an etching gas and the etching gas may be, for example N₂/O₂, CHF₃, CF₄, Cl₂, BCl₃, and a mixed gas thereof.

The etched material layer may be formed in a plurality of patterns, and the plurality of patterns may be a metal pattern, a semiconductor pattern, an insulation pattern, or the like, for example diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Examples 1 to 3: Synthesis of Monomer

### Synthesis Example 1

1,4-Bis(9-hydroxy-9-fluorenyl)benzene was prepared by mixing 2 molar equivalents of fluorenone and 1 molar equivalent of p-dibromobenzene as shown in Reaction Scheme 1 below, and 2 molar equivalents of phenol were added thereto and reacted therewith, obtaining Monomer 1 represented by Chemical Formula X1.

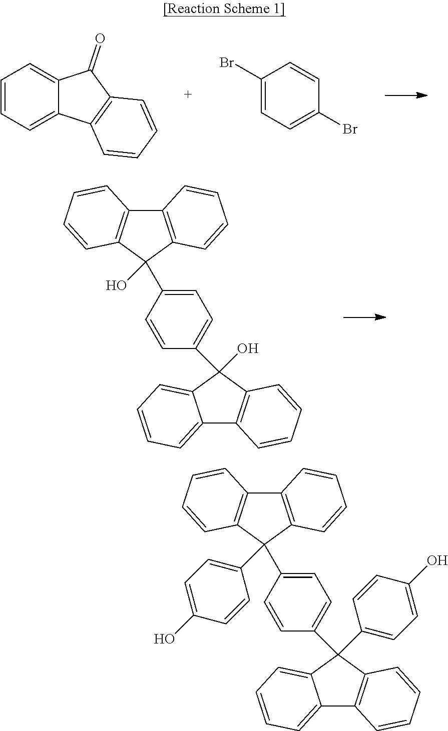

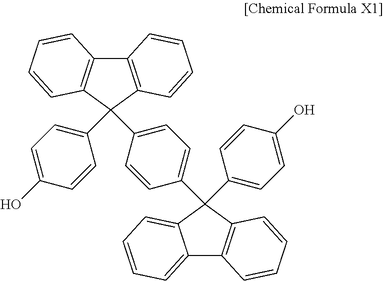 [SMILES: Oc1ccc(C2(c3ccc(C4(c5ccc(O)cc5)c5ccccc5-c5ccccc54)cc3)c3ccccc3-c3ccccc32)cc1]

### Synthesis Example 2

Monomer 2 represented by Chemical Formula X2 was obtained by mixing 2 molar equivalents of fluorenone and 1 molar equivalent of 4,4′-dibromobiphenyl to prepare 9-[4-[4-(9-hydroxy-1,2-dihydrofluoren-9-yl)phenyl]phenyl]fluoren-9-ol and then, adding 2 molar equivalents of phenol thereto and reacting them.

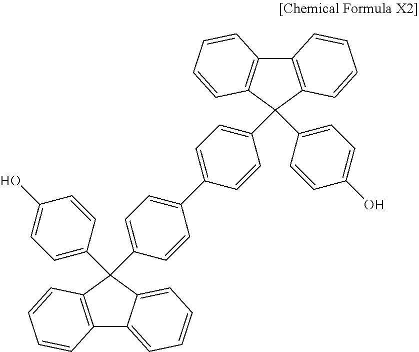 [SMILES: Oc1ccc(C2(c3ccc(-c4ccc(C5(c6ccc(O)cc6)c6ccccc6-c6ccccc65)cc4)cc3)c3ccccc3-c3ccccc32)cc1]

### Synthesis Example 3

Monomer 3 represented by Chemical Formula X3 was obtained by mixing 2 molar equivalents of fluorenone and 1 molar equivalent of bis-(4-bromophenyl)ether and then, adding 2 molar equivalents of 2-naphthol thereto and reacting them.

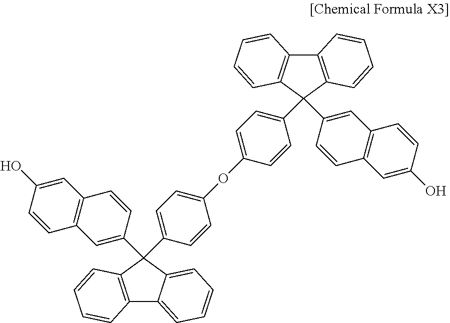 [SMILES: Oc1ccc2cc(C3(c4ccc(Oc5ccc(C6(c7ccc8cc(O)ccc8c7)c7ccccc7-c7ccccc76)cc5)cc4)c4ccccc4-c4ccccc43)ccc2c1]

### Synthesis Examples 4 to 8: Synthesis of Polymer

### Synthesis Example 4

In Synthesis Example 4, 1 mol of the monomer represented by Chemical Formula X1 according to Synthesis Example 1, 1 mol of 1,4-bis(methoxymethyl)benzene, and 250 g of propylene glycol monomethylether acetate (PGMEA) as a solvent were prepared into a solution. Then, 10 mmol of diethyl sulfate was added to the solution and then, stirred at 100° C. for 24 hours. When polymerization was completed, the resultant was precipitated in methanol to remove monomers and low molecular weight substance, obtaining a polymer including a structural unit represented by Chemical Formula 1-1a. (Mw: 6,540 g/mol)

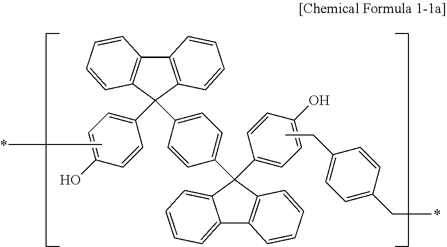

### Synthesis Example 5

A polymer including a structural unit represented by Chemical Formula 1-2a was obtained in the same manner as in Synthesis Example 4 except that the monomer represented by Chemical Formula X2 according to Synthesis Example 2 was used instead of the monomer according to Synthesis Example 1. (Mw: 4,318 g/mol)

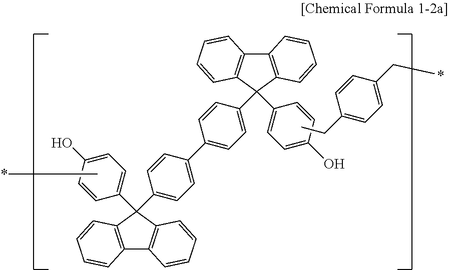

### Synthesis Example 6

In Synthesis Example 6, 1 mol of the monomer represented by Chemical Formula X2 according to Synthesis Example 2, 1 mol of 4,4′-bismethoxymethyl diphenylether, and 250 g of propylene glycol monomethylether acetate (PGMEA) as a solvent were prepared into a solution. Then, 5 mmol of diethyl sulfate was added to the solution and then, stirred at 100° C. for 24 hours. When polymerization was completed, the resultant was precipitated in methanol to remove monomers and low molecular weight substances, obtaining a polymer including a structural unit represented by Chemical Formula 1-2b. (Mw: 3,950 g/mol)

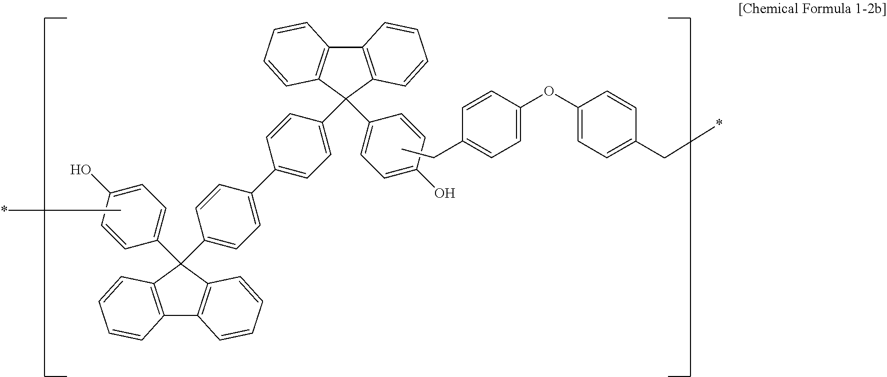

### Synthesis Example 7

A polymer including a structural unit represented by Chemical Formula 1-7a was obtained in the same manner as in Synthesis Example 4 except that the monomer represented by Chemical Formula X3 according to Synthesis Example 3 was used instead of the monomer according to Synthesis Example 1. (Mw: 3,381 g/mol)

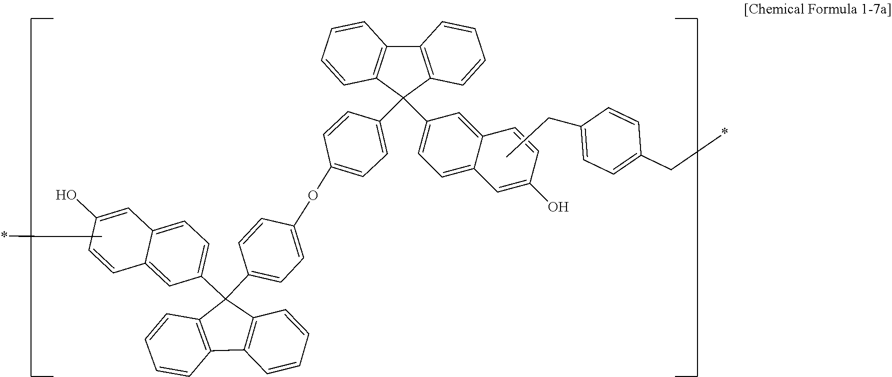

### Synthesis Example 8

In Synthesis Example 8, 1 mol of the monomer represented by Chemical Formula X3 according to Synthesis Example 3, 1 mol of 4,4′-bismethoxymethyl diphenylether, and 50 g of propylene glycol monomethylether acetate as a solvent were used, preparing a solution. Then, 5 mmol of diethyl sulfate was added to the solution and then, stirred at 100° C. for 24 hours. When polymerization was completed, the resultant was precipitated in methanol to remove monomers and low molecular weight substances, obtaining a polymer including a structural unit represented by Chemical Formula 1-7b. (Mw: 3,127 g/mol)

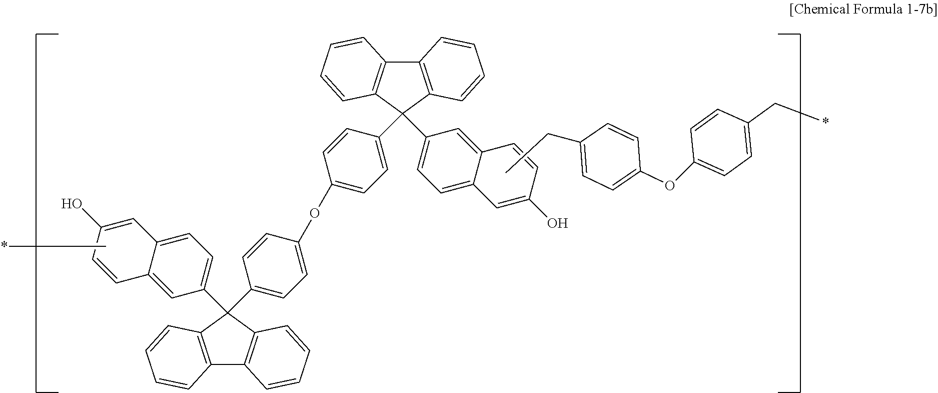

### Comparative Synthesis Example 1

In Comparative Synthesis Example 1, 1 mol of the monomer represented by Chemical Formula X1 according to Synthesis Example 1, 1 mol of paraformaldehyde, and 250 g of propylene glycol monomethylether acetate (PGMEA) as a solvent were prepared into a solution. Then, 7 mmol of diethyl sulfate was added to the solution and then, stirred at 100° C. for 24 hours. When polymerization was completed, the resultant was precipitated in methanol to remove monomers and low molecular weight substances, obtaining a polymer including a structural unit represented by Chemical Formula a. (Mw: 8,900 g/mol)

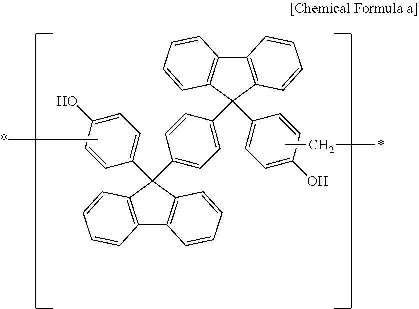

### Comparative Synthesis Example 2

In Comparative Synthesis Example 2, 1 mol of the monomer represented by Chemical Formula X2 according to Synthesis Example 2, 1 mol of paraformaldehyde, and 250 g of propylene glycol monomethylether acetate (PGMEA) as a solvent were prepared into a solution. Then, 7 mmol of diethyl sulfate was added to the solution and then, stirred at 100° C. for 24 hours. When polymerization was completed, the resultant was precipitated in methanol to remove monomers and low molecular weight substances, obtaining a polymer including a structural unit represented by Chemical Formula b. (Mw: 13,200 g/mol)

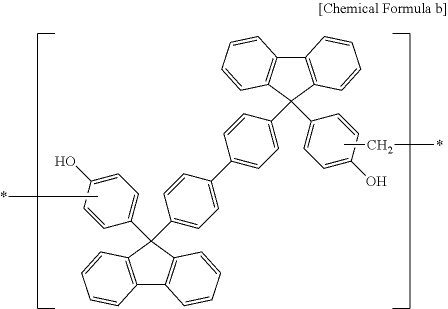

### Comparative Synthesis Example 3

In Comparative Synthesis Example 3, 50.0 g (0.143 mol) of 9,9′-bis(4-hydroxyphenyl)fluorene, 23.7 g (0.143 mol) of 1,4-bis(methoxymethyl)benzene, and 50 g of propylene glycol monomethylether acetate as a solvent were put in a flask to prepare a solution. Then, 1.10 g (7.13 mmol) of diethyl sulfate was added to the solution and then, stirred at 100° C. for 24 hours. When polymerization was completed, the resultant was precipitated in methanol to remove monomers and low molecular weight substances, obtaining a polymer including a structural unit represented by Chemical Formula c. (Mw: 33,500 g/mol)

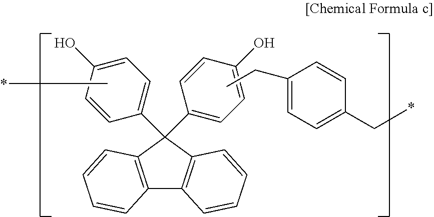

### Examples and Comparative Examples: Preparation of Hardmask Composition

### Example 1

3.3 g of the compound according to Synthesis Example 4 was dissolved in 30 g of propylene glycol monomethyl ether acetate (PGMEA) and then, filtered with a 0.1 m TEFLON (tetrafluoroethylene) filter, preparing a hardmask composition.

### Example 2

A hardmask composition was prepared in the same method as in Example 1 except that the compound of Synthesis Example 5 was used instead of the compound of Synthesis Example 4.

### Example 3

A hardmask composition was prepared in the same method as in Example 1 except that the compound of Synthesis Example 6 was used instead of the compound of Synthesis Example 4.

### Example 4

A hardmask composition was prepared in the same method as in Example 1 except that the compound of Synthesis Example 7 was used instead of the compound of Synthesis Example 4.

### Example 5

A hardmask composition was prepared in the same method as in Example 1 except that the compound of Synthesis Example 8 was used instead of the compound of Synthesis Example 4.

### Comparative Example 1

A hardmask composition was prepared in the same method as in Example 1 except that the compound of Comparative Synthesis Example 1 was used instead of the compound of Synthesis Example 4.

### Comparative Example 2

A hardmask composition was prepared in the same method as in Example 1 except that the compound of Comparative Synthesis Example 2 was used instead of the compound of Synthesis Example 4.

### Comparative Example 3

A hardmask composition was prepared in the same method as in Example 1 except that the compound of Comparative Synthesis Example 3 was used instead of the compound of Synthesis Example 4.

Evaluation 1: Evaluation of Gap-fill Characteristics and Planarization Characteristics

The FIGURE is a reference view exemplarily showing a step difference of a hardmask layer in order to explain a method for evaluating planarization characteristics.

The hardmask compositions according to Examples 1 to 5 and Comparative Examples 1 to 3 were respectively applied on a silicon pattern wafer by adjusting a mass ratio of solvent to solute into 3 to 97 and then, baked, forming 1,100 Å-thick organic films.

The gap-fill characteristics were evaluated by observing pattern cross-sections of the films by using a scanning electron microscope (SEM) to determine the presence or absence of voids thereon. The planarization characteristics (step difference measurement) of the films were evaluated by measuring each thickness in a peri region and a cell region on the scanning electron microscope (SEM) images.

Step difference results were calculated by h0-h4. The results are shown in Table 1.

TABLE 1

| | Gap-fill | |
|---|---|---|
| | characteristics | Planarization |
| | (presence | characteristics |
| | of voids) | (step difference, Å) |
| Example 1 | No | 196 |
| Example 2 | No | 175 |
| Example 3 | No | 89 |
| Example 4 | No | 132 |
| Example 5 | No | 77 |
| Comparative | Yes | Unmeasurable |
| Example 1 | | |
| Comparative | Yes | Unmeasurable |
| Example 2 | | |
| Comparative | No | 157 |
| Example 3 | | |

Referring to Table 1, the organic films formed of the hardmask compositions according to Examples 1 to 5 exhibited excellent planarization characteristics and gap-fill characteristics, compared with the organic films formed of the hardmask compositions according to Comparative Examples 1 to 2.

Evaluation 2: Evaluation of Etch Resistance

To evaluate etch resistance, 15 wt % of each hardmask composition of Examples 1 to 5 and Comparative Examples 1 to 3 was spin-on coated on a silicon wafer and then, heat-treated on a hot plate at 400° C. for 2 minutes, forming 4000 Å-thick thin films. The thin films were measured with respect to a thickness by using a thin film thickness meter made by K-MAC. Subsequently, the thin films were dry etched by using a CHF₃/CF₄ mixed gas and an N₂/O₂ mixed gas for 100 seconds and 60 seconds, respectively and then, measured with respect to a thickness to calculate a thickness difference of each organic film before and after the dry etching, which was used with etch time to calculate a bulk etch rate (BER) according to Calculation Equation 1. The results are shown in Table 2.

$$Etch rate ( Å / s ) = \frac{( \begin{matrix}initial thin film thickness - \\ thin film thickness after etching\end{matrix} )}{etch time ( sec )} \qquad [ Calculation Equation 1 ]$$

TABLE 2

| | CFₓ Bulk | N₂/O₂ Bulk |
|---|---|---|
| | etch rate | etch rate |
| | (Å/s) | (Å/s) |
| Example 1 | 30.1 | 28.6 |
| Example 2 | 30.4 | 29.8 |
| Example 3 | 29.5 | 27.5 |
| Example 4 | 28.6 | 27.5 |
| Example 5 | 28.1 | 26.2 |
| Comparative | 28.4 | 29.4 |
| Example 1 | | |
| Comparative | 30.7 | 32.0 |
| Example 2 | | |
| Comparative | 29.0 | 30.3 |
| Example 3 | | |

Referring to Table 2, the thin films formed of the hardmask compositions according to Examples 1 to 5 exhibited similar low etch rates, compared with those of the thin films formed of the hardmask compositions according to Comparative Examples 1 to 3. Accordingly, the hardmask compositions according to Examples 1 to 5 exhibited similar or high etch resistance, compared with that of the hardmask compositions according to Comparative Examples 1 to 3.

Evaluation 3: Solubility Evaluation

The hardmask compositions according to Examples 1 to 5 and Comparative Examples 1 to 3 were stored at a low temperature (3° C. or less) for 3 months and then, examined with respect to an amount of precipitates.

When a solid was not visually precipitated in a solution with naked eyes, solubility was evaluated to be excellent.

In Table 3, when a solid was precipitated in a solution, 0 is given, but when not precipitated, X is given.

TABLE 3

| | Precipitated |
|---|---|
| | or not |
| Example 1 | X |
| Example 2 | X |
| Example 3 | X |
| Example 4 | X |
| Example 5 | X |
| Comparative | O |
| Example 1 | |
| Comparative | O |
| Example 2 | |
| Comparative | O |
| Example 3 | |

Referring to Table 3, Examples 1 to 5 exhibited improved solubility, compared with Comparative Examples 1 to 3.

By way of summation and review, a general lithographic technique may include providing a material layer on a semiconductor substrate, coating a photoresist layer thereon, exposing and developing the same to provide a photoresist pattern, and etching a material layer using the photoresist pattern as a mask. According to a small size of a pattern to be formed, it may be difficult to provide a fine pattern having an excellent profile using only the general lithographic technique. Accordingly, an auxiliary layer, e.g., a hardmask layer, may be formed between the material layer and the photoresist layer to provide a fine pattern.

As described above, an embodiment may provide a hardmask composition that can be effectively applied to a hardmask layer. An embodiment may provide a hardmask layer including a cured product of the hardmask composition. An embodiment may provide a method of forming patterns using the hardmask composition.

A hardmask composition according to an embodiment may have excellent solubility in a solvent and thus may be effectively applied to the hardmask layer.

A hardmask layer formed from a hardmask composition according to an embodiment may secure excellent gap-fill characteristics, planarization characteristics, and etch resistance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1 and a structural unit represented by Chemical Formula 2; and
a solvent: 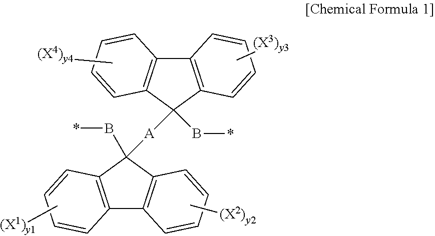
wherein, in Chemical Formula 1,
A is a linking group including one or more benzene rings, and when it includes two or more benzene rings, two or more benzene rings form a condensed ring, or two or more benzene rings are linked to each other by a single bond, —O—, —S—, —NR¹— in which R¹ is hydrogen, a C1 to C10 alkyl group, or a C6 to C30 aryl group, —C(═O)—, —(CH₂)ₘ—(CR²R³)ₙ—(CH₂)ₒ— in which R² and R³ is each independently hydrogen, a C1 to C10 alkyl group, a C6 to C20 aryl group, or a C3 to C10 cycloalkyl group, m, n, and o are each independently an integer from 0 to 10, and m+n+o is 1 or more, or a combination thereof,
B is a C6 to C30 aromatic hydrocarbon ring substituted with one or more hydroxy groups or C1 to C10 alkoxy groups,
X¹ to X⁴ are each independently deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group,
y1 to y4 are each independently an integer of 0 to 4, and
* is a linking point; 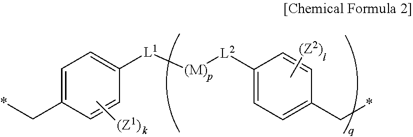
wherein, in Chemical Formula 2,
L¹ and L² are each independently a single bond, a substituted or unsubstituted divalent C1 to C15 saturated aliphatic hydrocarbon group, or a substituted or unsubstituted divalent C2 to C15 unsaturated aliphatic hydrocarbon group,
M is —O—, —S—, —SO₂—, or —C(═O)—,
Z¹ and Z² are each independently deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group,
k, l, and q are each independently an integer of 0 to 4,
p is 0 or 1, and
* is a linking point.

2. The hardmask composition as claimed in claim 1, wherein A in Chemical Formula 1 is any one selected from Group 1: 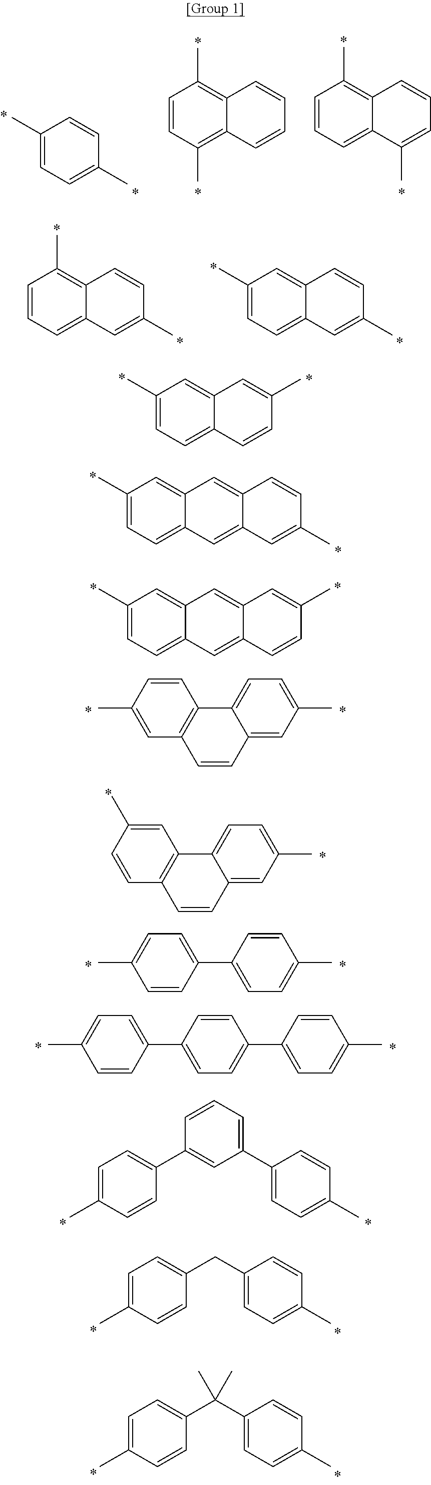 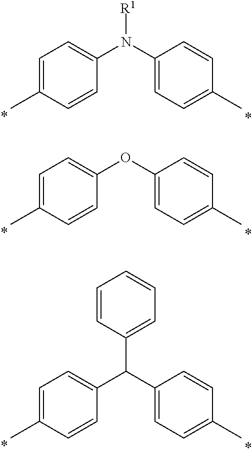
wherein, in Group 1,
R¹ is hydrogen, a C1 to C10 alkyl group, or a C6 to C30 aryl group, and
* is a linking point.

3. The hardmask composition as claimed in claim 1, wherein B in Chemical Formula 1 is any one selected from Group 2 substituted with one or more hydroxyl groups or C1 to C10 alkoxy groups:

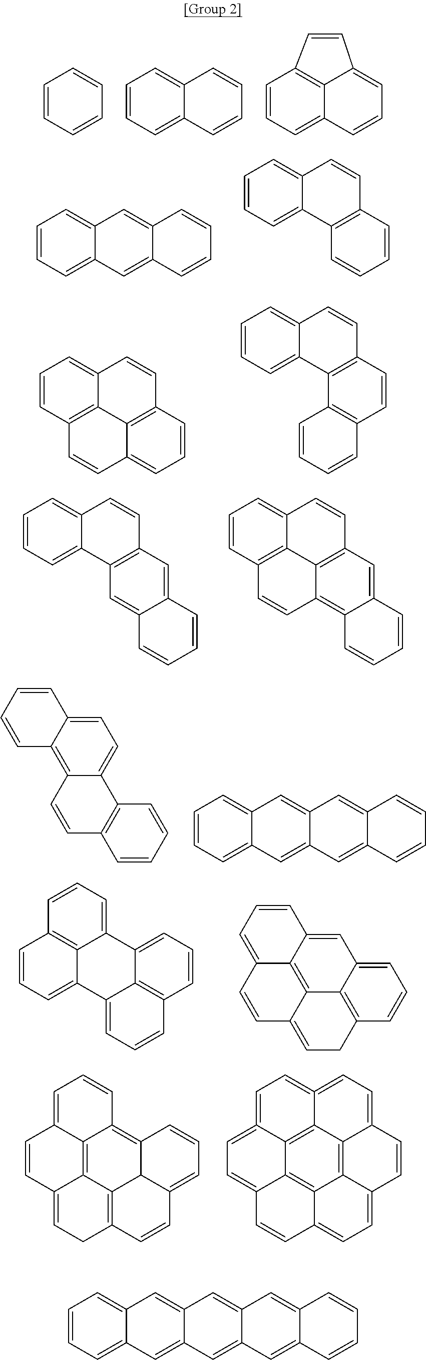

4. The hardmask composition as claimed in claim 1, wherein in Chemical Formula 2,
L¹ and L² are each independently a single bond, or a substituted or unsubstituted C1 to C10 alkylene group,
M is —O—,
Z¹ and Z² are each independently deuterium, a hydroxy group, a halogen, a substituted or unsubstituted C1 to C30 alkoxy group, or a substituted or unsubstituted C1 to C30 saturated aliphatic hydrocarbon group,
k and l are each independently one of integers of 0 to 2, and
p and q are each 0 or 1.

5. The hardmask composition as claimed in claim 1, wherein A in Chemical Formula 1 is any one selected from Group 1-1: 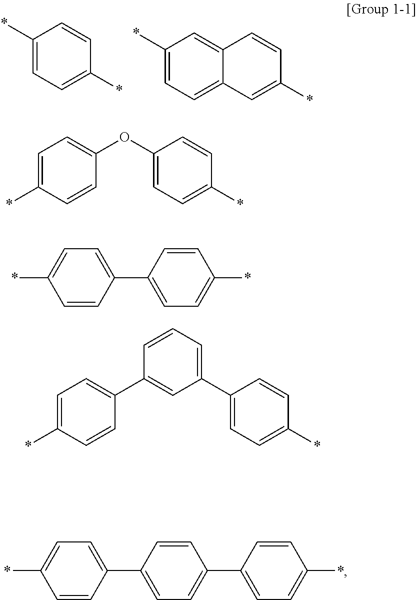
wherein * is a linking point.

6. The hardmask composition as claimed in claim 1, wherein B in Chemical Formula 1 is any one selected from Group 2-1: 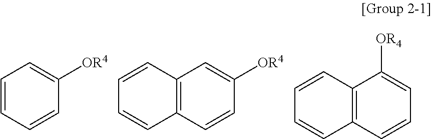
wherein, in Group 2-1,
R⁴ is hydrogen, a C1 to C10 alkyl group, a C2 to C10 alkenyl group, or a C2 to C10 alkynyl group.

7. The hardmask composition as claimed in claim 1, wherein Chemical Formula 1 is any one of Chemical Formula 1-1 to Chemical Formula 1-11: 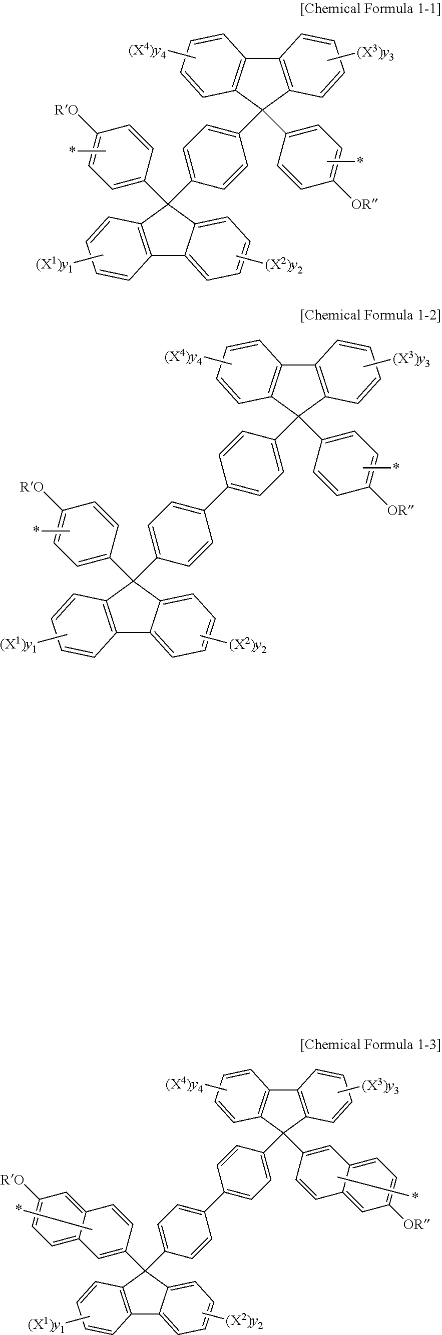 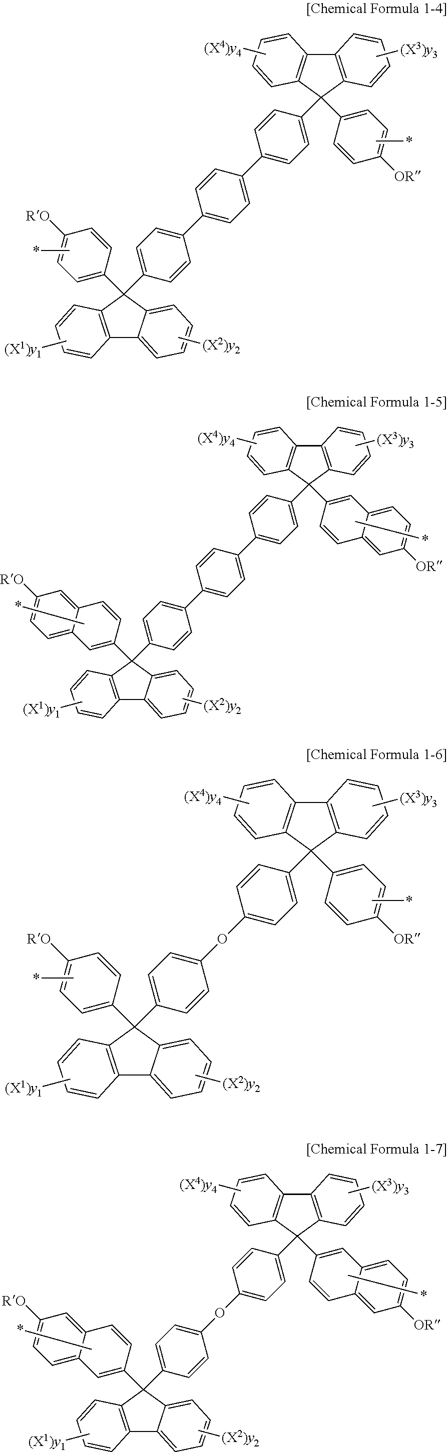 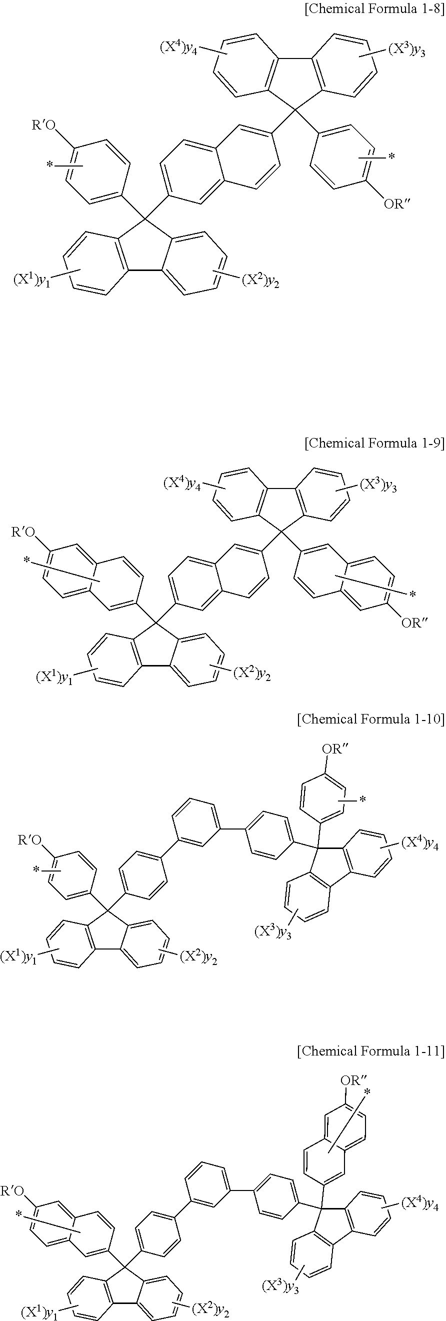
wherein, in Chemical Formula 1-1 to Chemical Formula 1-11,
R′ and R″ are each independently hydrogen, a C1 to C10 alkyl group, a C2 to C10 alkenyl group, or a C2 to C10 alkynyl group,
X¹ to X⁴ are each independently deuterium, a hydroxy group, a halogen, a substituted or unsubstituted C1 to C30 alkoxy group, a substituted or unsubstituted C1 to C30 saturated aliphatic hydrocarbon group, a substituted or unsubstituted C2 to C30 unsaturated aliphatic hydrocarbon group, a substituted or unsubstituted C6 to C30 aromatic hydrocarbon group, a substituted or unsubstituted C1 to C30 heteroalkyl group, or a substituted or unsubstituted C2 to C30 heteroaromatic hydrocarbon group,
y1 to y4 are each independently an integer of 0 to 4, and
* is a linking point.

8. The hardmask composition as claimed in claim 1, wherein Chemical Formula 2 is represented by Chemical Formula 2-1 or Chemical Formula 2-2: 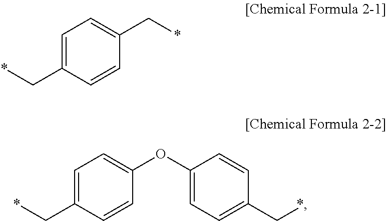
wherein * is a linking point.

9. The hardmask composition as claimed in claim 1, wherein the polymer has a weight average molecular weight of about 1,000 g/mol to about 200,000 g/mol.

10. The hardmask composition as claimed in claim 1, wherein the polymer is included in an amount of about 0.1 wt % to about 30 wt % based on the total weight of the hardmask composition.

11. The hardmask composition as claimed in claim 1, wherein the solvent is propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

12. A hardmask layer comprising a cured product of the hardmask composition as claimed in claim 1.

13. A method of forming patterns, comprising:
providing a material layer on a substrate,
applying the hardmask composition as claimed in claim 1 on the material layer,
heat-treating the applied hardmask composition to form a hardmask layer,
forming a photoresist layer on the hardmask layer,
exposing and developing the photoresist layer to form a photoresist pattern,
selectively removing the hardmask layer using the photoresist pattern, to expose a portion of the material layer, and
etching the exposed portion of the material layer.

14. The method as claimed in claim 13, wherein the forming of the hardmask layer includes heat-treating at about 100° C. to about 1,000° C.
